(19) United States
(12) Patent Application Publication
(10) Pub. No.: US 2023/0296979 A1
(43) Pub. Date: Sep. 21, 2023

(54) TEMPLATE AND MANUFACTURING METHOD OF SEMICONDUCTOR DEVICE

(71) Applicant: Kioxia Corporation, Tokyo (JP)

(72) Inventors: Takeharu MOTOKAWA, Zushi Kanagawa (JP); Noriko SAKURAI, Yokohama Kanagawa (JP); Hideaki SAKURAI, Kawasaki Kanagawa (JP)

(73) Assignee: Kioxia Corporation, Tokyo (JP)

(21) Appl. No.: 17/842,615

(22) Filed: Jun. 16, 2022

(30) Foreign Application Priority Data
Mar. 15, 2022 (JP) 2022-040705

(51) Int. Cl. G03F 7/00; H01L 21/3105

(52) U.S. Cl. CPC G03F 7/0002; H01L 21/31058

(57) ABSTRACT

A template according to the present embodiment includes a substrate, a light transmissive film, and a plurality of convex parts. The substrate has a first surface. The light transmissive film is provided on the first surface, has a second surface on a side opposite to the substrate, and has a composition different from the composition of the substrate. The plurality of convex parts are provided on the second surface and have different heights.

### CROSS REFERENCE TO RELATED APPLICATIONS

This application is based upon and claims the benefit of priority from the prior Japanese Patent Application No. 2022-040705, filed on Mar. 15, 2022, the entire contents of which are incorporated herein by reference.

### FIELD

The embodiments of the present invention relate to a template and a manufacturing method of a semiconductor device.

### BACKGROUND

In a known technology of manufacturing a semiconductor device by using a nanoimprint method with which a minute pattern can be formed, a template having a concave-convex pattern region is pressed against a resist applied on a processing target film, and the processing target film is processed by using, as a mask, the resist on which the pattern is formed.

### BRIEF DESCRIPTION OF THE DRAWINGS

FIG. 1 is a cross sectional view illustrating the structure of a semiconductor device according to a first embodiment;

FIG. 2 is a cross sectional view illustrating an exemplary manufacturing method of the semiconductor device according to the first embodiment;

FIG. 3 is a cross sectional view illustrating the exemplary manufacturing method of the semiconductor device, continued from FIG. 2;

FIG. 4 is a cross sectional view illustrating the exemplary manufacturing method of the semiconductor device, continued from FIG. 3;

FIG. 5 is a cross sectional view illustrating the exemplary manufacturing method of the semiconductor device, continued from FIG. 4;

FIG. 6 is a cross sectional view illustrating an exemplary configuration of a template according to the first embodiment;

FIG. 7A is a cross sectional view illustrating an exemplary manufacturing method of the template according to the first embodiment;

FIG. 7B is a cross sectional view illustrating the exemplary manufacturing method of the template, continued from FIG. 7A;

FIG. 7C is a cross sectional view illustrating the exemplary manufacturing method of the template, continued from FIG. 7B;

FIG. 7D is a cross sectional view illustrating the exemplary manufacturing method of the template, continued from FIG. 7C;

FIG. 7E is a cross sectional view illustrating the exemplary manufacturing method of the template, continued from FIG. 7D;

FIG. 8A is a cross sectional view illustrating an exemplary forming method of a stepped pattern according to the first embodiment;

FIG. 8B is a cross sectional view illustrating the exemplary forming method of the stepped pattern, continued from FIG. 8A;

FIG. 8C is a cross sectional view illustrating the exemplary forming method of the stepped pattern, continued from FIG. 8B;

FIG. 8D is a cross sectional view illustrating the exemplary forming method of the stepped pattern, continued from FIG. 8C;

FIG. 8E is a cross sectional view illustrating the exemplary forming method of the stepped pattern, continued from FIG. 8D;

FIG. 8F is a cross sectional view illustrating the exemplary forming method of the stepped pattern, continued from FIG. 8E;

FIG. 8G is a cross sectional view illustrating the exemplary forming method of the stepped pattern, continued from FIG. 8F;

FIG. 9 is a cross sectional view illustrating an exemplary configuration of a template according to a comparative example;

FIG. 10A is a cross sectional view illustrating an exemplary manufacturing method of the template according to the comparative example;

FIG. 10B is a cross sectional view illustrating the exemplary manufacturing method of the template, continued from FIG. 10A;

FIG. 10C is a cross sectional view illustrating the exemplary manufacturing method of the template, continued from FIG. 10B;

FIG. 10D is a cross sectional view illustrating the exemplary manufacturing method of the template, continued from FIG. 10C;

FIG. 10E is a cross sectional view illustrating the exemplary manufacturing method of the template, continued from FIG. 10D;

FIG. 10F is a cross sectional view illustrating the exemplary manufacturing method of the template, continued from FIG. 10E;

FIG. 11A is a cross sectional view illustrating an exemplary manufacturing method of a template according to a first modification of the first embodiment;

FIG. 11B is a cross sectional view illustrating the exemplary manufacturing method of the template, continued from FIG. 11A;

FIG. 11C is a cross sectional view illustrating the exemplary manufacturing method of the template, continued from FIG. 11B;

FIG. 11D is a cross sectional view illustrating the exemplary manufacturing method of the template, continued from FIG. 11C;

FIG. 11E is a cross sectional view illustrating the exemplary manufacturing method of the template, continued from FIG. 11D;

FIG. 11F is a cross sectional view illustrating the exemplary manufacturing method of the template, continued from FIG. 11E;

FIG. 12A is a cross sectional view illustrating an exemplary manufacturing method of a template according to a second modification of the first embodiment;

FIG. 12B is a cross sectional view illustrating the exemplary manufacturing method of the template, continued from FIG. 12A;

FIG. 12C is a cross sectional view illustrating the exemplary manufacturing method of the template, continued from FIG. 12B;

FIG. 12D is a cross sectional view illustrating the exemplary manufacturing method of the template, continued from FIG. 12C;

FIG. 12E is a cross sectional view illustrating the exemplary manufacturing method of the template, continued from FIG. 12D;

FIG. 12F is a cross sectional view illustrating the exemplary manufacturing method of the template, continued from FIG. 12E;

FIG. 13 is a cross sectional view illustrating an exemplary configuration of a template according to a third modification of the first embodiment;

FIG. 14A is a cross sectional view illustrating an exemplary manufacturing method of the template according to the third modification of the first embodiment;

FIG. 14B is a cross sectional view illustrating the exemplary manufacturing method of the template, continued from FIG. 14A;

FIG. 14C is a cross sectional view illustrating the exemplary manufacturing method of the template, continued from FIG. 14B;

FIG. 14D is a cross sectional view illustrating the exemplary manufacturing method of the template, continued from FIG. 14C;

FIG. 14E is a cross sectional view illustrating the exemplary manufacturing method of the template, continued from FIG. 14D;

FIG. 14F is a cross sectional view illustrating the exemplary manufacturing method of the template, continued from FIG. 14E;

FIG. 15 is a cross sectional view illustrating an exemplary configuration of a template according to a second embodiment;

FIG. 16A is a cross sectional view illustrating an exemplary manufacturing method of the template according to the second embodiment;

FIG. 16B is a cross sectional view illustrating the exemplary manufacturing method of the template, continued from FIG. 16A;

FIG. 16C is a cross sectional view illustrating the exemplary manufacturing method of the template, continued from FIG. 16B;

FIG. 16D is a cross sectional view illustrating the exemplary manufacturing method of the template, continued from FIG. 16C;

FIG. 16E is a cross sectional view illustrating the exemplary manufacturing method of the template, continued from FIG. 16D;

FIG. 17A is a cross sectional view illustrating an exemplary manufacturing method of a template according to a modification of the second embodiment;

FIG. 17B is a cross sectional view illustrating the exemplary manufacturing method of the template, continued from FIG. 17A;

FIG. 17C is a cross sectional view illustrating the exemplary manufacturing method of the template, continued from FIG. 17B;

FIG. 17D is a cross sectional view illustrating the exemplary manufacturing method of the template, continued from FIG. 17C;

FIG. 18 is a cross sectional view illustrating an exemplary configuration of a template according to a third embodiment;

FIG. 19A is a cross sectional view illustrating an exemplary manufacturing method of the template according to the third embodiment;

FIG. 19B is a cross sectional view illustrating the exemplary manufacturing method of the template, continued from FIG. 19A;

FIG. 19C is a cross sectional view illustrating the exemplary manufacturing method of the template, continued from FIG. 19B;

FIG. 19D is a cross sectional view illustrating the exemplary manufacturing method of the template, continued from FIG. 19C; and

FIG. 19E is a cross sectional view illustrating the exemplary manufacturing method of the template, continued from FIG. 19D.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A template according to the present embodiment includes a substrate, a light transmissive film, and a plurality of convex parts. The substrate has a first surface. The light transmissive film is provided on the first surface, has a second surface on a side opposite to the substrate, and has a composition different from the composition of the substrate. The plurality of convex parts are provided on the second surface and have different heights.

### First Embodiment

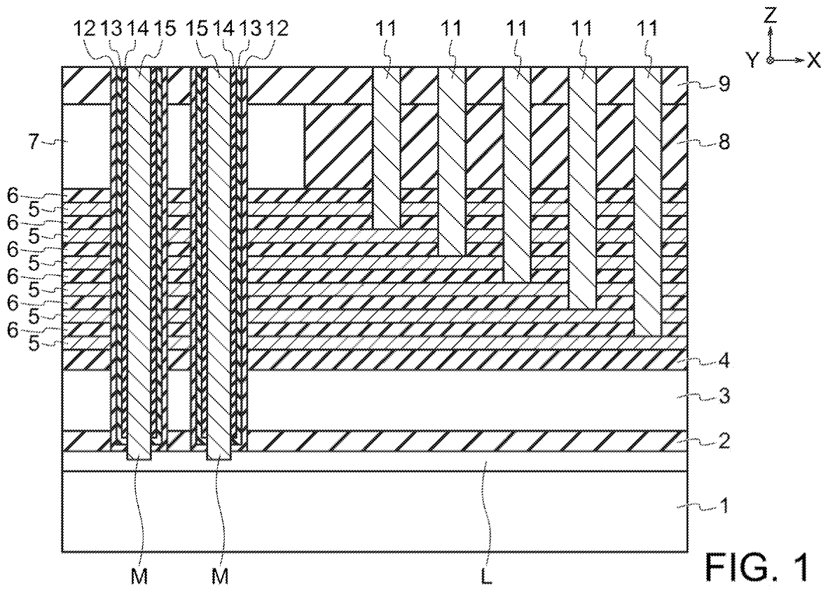

FIG. 1 is a cross sectional view illustrating the structure of a semiconductor device according to a first embodiment. The semiconductor device in FIG. 1 includes a three-dimensional semiconductor memory.

The semiconductor device in FIG. 1 includes a substrate 1, a first insulating film 2, a source side conductive layer 3, a second insulating film 4, a plurality of electrode layers 5 as exemplary first films, a plurality of insulating layers 6 as exemplary second films, a drain side conductive layer 7, a first interlayer insulating film 8, a second interlayer insulating film 9, a plurality of contact plugs 11, a first memory insulating film 12, an electric charge accumulation layer 13, a second memory insulating film 14, and a channel semiconductor layer 15.

The substrate 1 is a semiconductor substrate such as a silicon substrate. FIG. 1 illustrates an X direction and a Y direction that are parallel to the top surface of the substrate 1 and orthogonal to each other, and a Z direction orthogonal to the top surface of the substrate 1. In the present specification, a positive Z direction is defined as an upward direction, in other words, a height direction, and a negative Z direction is defined as a downward direction. The negative Z direction may or may not align with the direction of gravity. In the following description, “height” may be interpreted as “thickness”.

The first insulating film 2 is formed on a diffusion layer L formed in the substrate 1. The source side conductive layer 3 is formed on the first insulating film 2. The second insulating film 4 is formed on the source side conductive layer 3.

The plurality of electrode layers 5 and the plurality of insulating layers 6 are alternately laminated on the second insulating film 4. Each electrode layer 5 is for example, a metal layer containing tungsten (W) or molybdenum (Mo) and functions as a word line or a selection line. Each insulating layer 6 is, for example, a silicon oxide film.

The drain side conductive layer 7 and the first interlayer insulating film 8 are formed on a laminated body including the electrode layers 5 and the insulating layers 6. The second interlayer insulating film 9 is formed on the drain side conductive layer 7 and the first interlayer insulating film 8.

The plurality of contact plugs 11 are formed in contact holes penetrating through some of the electrode layers 5 and the insulating layers 6, the first interlayer insulating film 8, and the second interlayer insulating film 9. The contact plugs 11 are electrically connected to the respective electrode layers 5. Each contact plug 11 is formed of, for example, a barrier metal layer such as a titanium containing layer, and a plug material layer such as a tungsten layer.

In the present embodiment, a non-illustrated insulating film is formed between the side surface of each contact plug 11 and the side surface of each electrode layer 5 to avoid contact between the side surface of the contact plug 11 and the side surface of the electrode layer 5. The bottom surface of each contact plug 11 contacts the top surface of the corresponding electrode layer 5.

The first memory insulating film 12, the electric charge accumulation layer 13, and the second memory insulating film 14 are sequentially formed on the side surface of a memory hole M penetrating through the first insulating film 2, the source side conductive layer 3, the second insulating film 4, the electrode layers 5, the insulating layers 6, the drain side conductive layer 7, and the second interlayer insulating film 9. The channel semiconductor layer 15 is formed in the memory hole M through the first memory insulating film 12, the electric charge accumulation layer 13, and the second memory insulating film 14 and electrically connected to the substrate 1.

The first memory insulating film 12 is, for example, a silicon oxide film. The electric charge accumulation layer 13 is, for example, a silicon nitride film. The second memory insulating film 14 is, for example, a silicon oxide film. The channel semiconductor layer 15 is, for example, a polysilicon layer. The electric charge accumulation layer 13 may be a semiconductor layer such as a polysilicon layer.

These components are formed by, for example, sequentially forming the first memory insulating film 12, the electric charge accumulation layer 13, and the second memory insulating film 14 on the side and bottom surfaces of the memory hole M, removing the second memory insulating film 14, the electric charge accumulation layer 13, and the first memory insulating film 12 from the bottom surface of the memory hole M, and then embedding the channel semiconductor layer 15 in the memory hole M. A non-illustrated core insulator may be additionally embedded in the channel semiconductor layer 15.

Each contact plug 11 illustrated in FIG. 1 is formed by, for example, embedding a conductive material in a concave part (contact hole) formed by using a nanoimprint method.

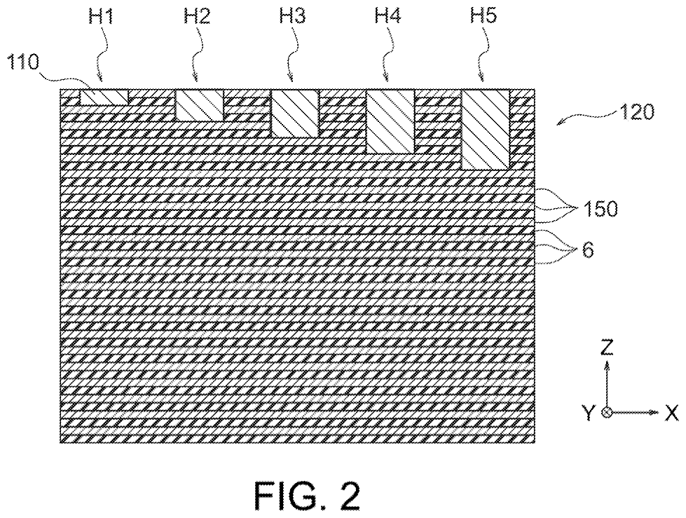

FIGS. 2 to 5 are cross sectional views illustrating an exemplary manufacturing method of the semiconductor device according to the first embodiment.

First, as illustrated in FIG. 2, a laminated body 120 including sacrifice layers 150 and the insulating layers 6 as exemplary first films alternately and repeatedly laminated in the height direction (positive Z direction) orthogonal to the top surface of the substrate 1 is formed on the substrate 1. Each sacrifice layer 150 is, for example, a silicon nitride film (SiN). Each insulating layer 6 is, for example, a silicon oxide film (SiO₂). In FIG. 2, illustration of the substrate 1 is omitted. The numbers of the sacrifice layers 150 and the insulating layers 6 are not particularly limited. Thereafter, a plurality of concave parts (contact holes H1 to H5) having different depths are formed in the laminated body 120, and a sacrifice layer 110 is formed inside each contact hole to fill the contact hole. The sacrifice layer 110 is, for example, a silicon oxide film or an amorphous silicon film.

Formation of the contact holes H1 to H5 will be described below in detail. In the embodiment, by using the nanoimprint method, a template pattern to be described later is transferred onto a non-illustrated resin (for example, a resist material) formed on a processing target film including the laminated body 120. Thereafter, the processing target film is processed by using, as a mask, the resin onto which the pattern is transferred, and accordingly, the contact holes H1 to H5 are formed in the laminated body 120.

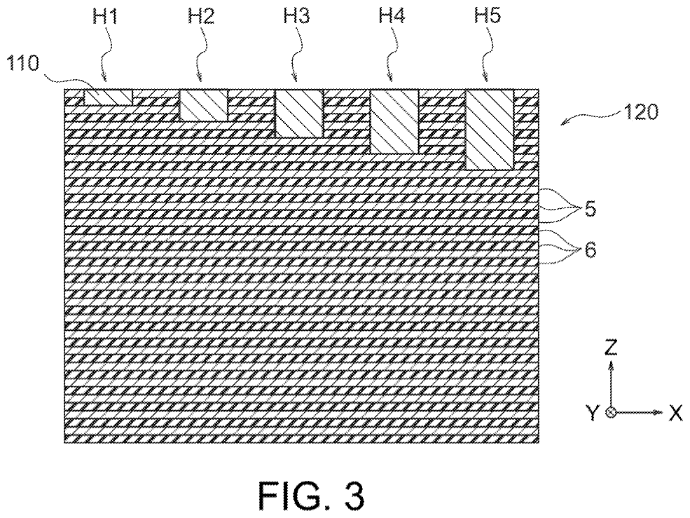

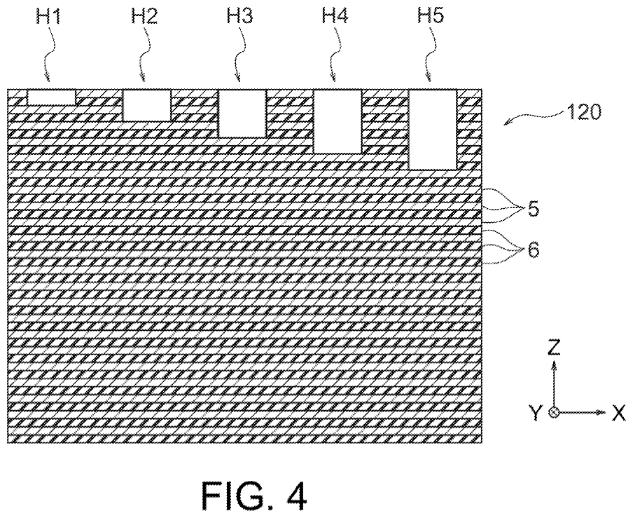

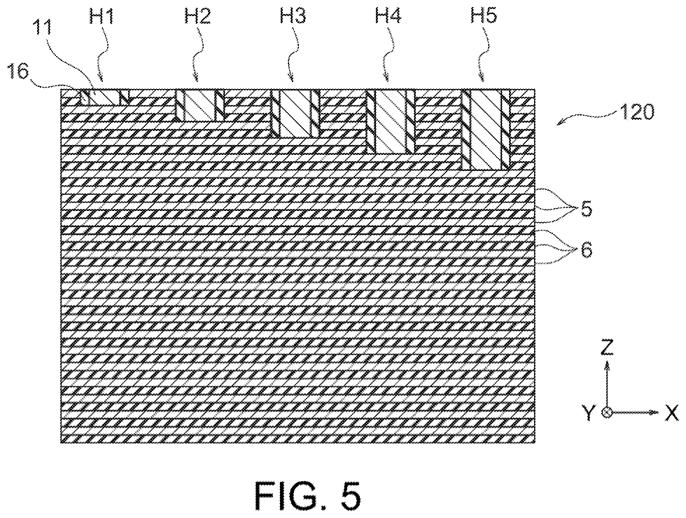

Then, after the sacrifice layers 110 are formed, a non-illustrated slit penetrating through the laminated body 120 is formed. After the slit is formed, the sacrifice layers 150 of the laminated body 120 are removed by wet etching with which the sacrifice layers 150 are processed with chemical solution introduced through the slit. After each sacrifice layer 150 is removed, each electrode layer 5 is deposited in a hollow space formed between the insulating layers 6 through the removal of the sacrifice layer 150. Accordingly, as illustrated in FIG. 3, the sacrifice layers 150 are replaced with the electrode layers 5. After the sacrifice layers 150 are replaced with the electrode layers 5, the sacrifice layers 110 formed inside the contact holes are removed as illustrated in FIG. 4. After the sacrifice layers 110 are removed, an insulating layer 16 is formed on the sidewall of each contact hole as illustrated in FIG. 5. After the insulating layers 16 are formed, the contact plugs 11 are formed by embedding plug material layers inside the respective insulating layers 16.

Formation of the contact plugs 11 is not limited to the above-described method. For example, after the plurality of contact holes H1 to H5 having different depths are formed, the insulating layers 16 may be formed on the sidewalls of the contact holes and plug material layers may be embedded inside the insulating layer 16 as illustrated in FIG. 5, and then the replacement as illustrated in FIG. 3 may be performed.

The following describes a template for forming a semiconductor device, in other words, a plurality of concave parts (the contact holes H1 to H5) having different depths. This template 100 may be used to form another region of the semiconductor device.

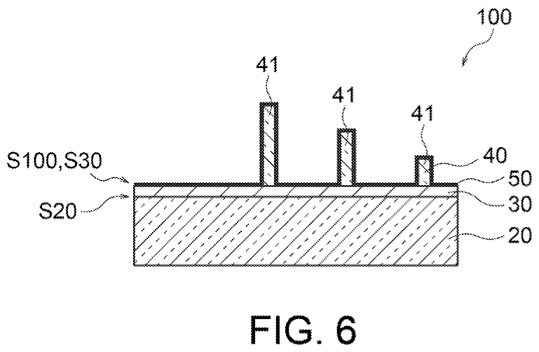

In the following description, the upward direction is the upward direction in the sheets of FIGS. 6 to 19E.

FIG. 6 is a cross sectional view illustrating an exemplary configuration of the template 100 according to the first embodiment.

The template 100 includes a surface S100 and a plurality of convex parts 41.

The surface S100 is a surface on which a concave-convex pattern is provided. In the nanoimprint method, the template 100 is pressed against a resist applied on the processing target film so that the concave-convex pattern is transferred onto the resist.

The plurality of convex parts 41 provided on the surface S100 constitute a pillar pattern as the concave-convex pattern. A plurality of concave parts (the contact holes H1 to H5) having different depths for forming the contact plugs 11 can be formed through transfer of the pillar pattern.

The template 100 includes a substrate 20, a transparent conductive film 30, a member 40, and a protective film 50.

The substrate 20 has a surface (first surface) S20 on the surface S100 side. The surface S20 has a substantially constant height in a direction substantially orthogonal to the surface S100. The substrate 20 is, for example, a light transmissive quartz glass substrate. Accordingly, the substrate 20 contains silicon dioxide (SiO₂).

The transparent conductive film (light transmissive film) 30 is provided in a film shape (layer shape) on the substrate 20. The transparent conductive film 30 has a surface (second surface) S30 on a side opposite the substrate 20. The composition of the transparent conductive film 30 is different from the composition of the substrate 20. Specifically, “different in composition” means that the transparent conductive film 30 and the substrate 20 are formed of different materials. The transparent conductive film 30 has a substantially constant height in the direction substantially orthogonal to the surface S100.

The transparent conductive film 30 is light transmissive so that transfer using light, for example, ultraviolet (UV) light is possible in the nanoimprint method. The optical transmittance of the transparent conductive film 30 is substantially equivalent to the optical transmittance of the quartz glass substrate as the substrate 20. The transparent conductive film 30 is also conductive. Accordingly, charge-up can be prevented. As a result, generation of micro trenches T can be prevented as described later. The composition of the transparent conductive film 30 is, for example, indium tin oxide (ITO) but not limited thereto. The composition ratio of In₂O₃ and SnO₂ in ITO changes depending on, for example, the composition ratio of a sputtering target. The composition ratio of In₂O₃ and SnO₂ is, for example, 95:5 to 80:20 but not limited thereto.

The member 40 is provided on the transparent conductive film 30. The member 40 includes the plurality of convex parts 41. The plurality of convex parts 41 are provided as protrusions toward the side opposite the substrate 20 from the top surface of the transparent conductive film 30 corresponding to the surface S100. The plurality of convex parts 41 have different heights. The heights of the convex parts 41 are heights in the direction substantially orthogonal to the surface S100. More specifically, the heights of the plurality of convex parts 41 differ in a stepped manner in accordance with the position of the surface S20. In other words, the heights of the convex parts 41 decrease or increase as the distance from an optional position on the surface S20 increases.

The composition of the convex parts 41, in other words, the composition of the member 40 is the same as the composition of the substrate 20. The member 40 and the substrate 20 are formed by different methods. The member 40 is formed by, for example, a sputtering method, and the substrate 20 is formed by, for example, synthesis. The composition of the convex parts 41, in other words, the composition of the member 40 is, for example, SiO₂.

The protective film 50 covers a surface layer of the concave-convex pattern of the template 100. The protective film 50 covers the plurality of convex parts 41 and the surface S100. More specifically, the protective film 50 is provided along a top surface part and a side surface part of each convex part 41 and the top surface of the transparent conductive film 30. When the transparent conductive film 30 is exposed on the topmost surface layer of the template 100, it is likely that a property such as surface force is adversely affected. With the protective film 50, a surface property or a surface state (for example, release force in the nanoimprint method) can be adjusted through composition unification. The composition of the protective film 50 is the same as the composition of the substrate 20. The composition of the protective film 50 is, for example, SiO₂.

The following describes a manufacturing method of the template 100.

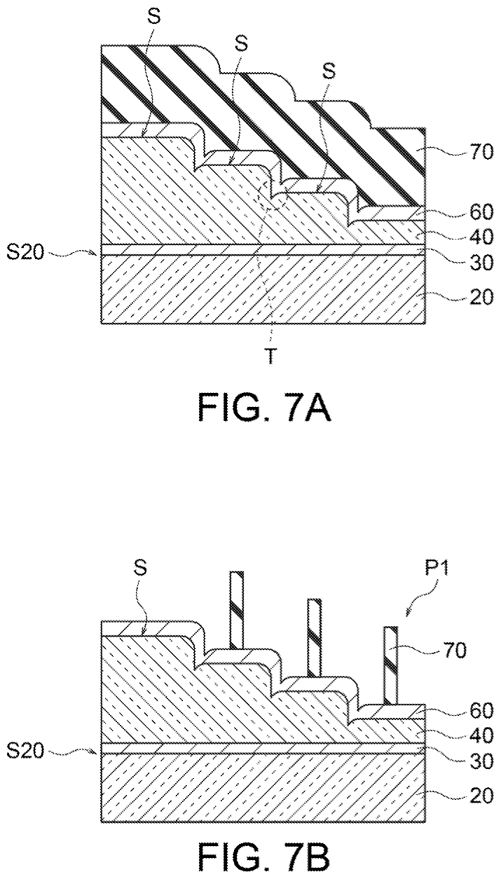

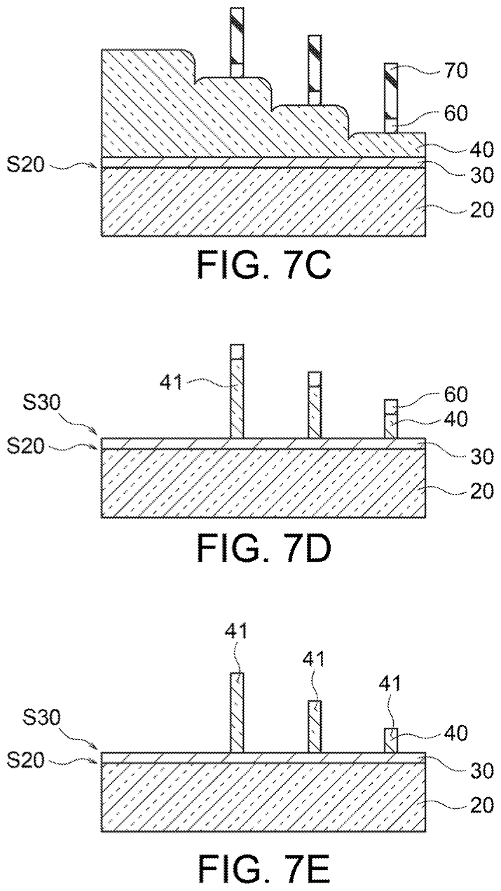

FIGS. 7A to 7E are cross sectional views illustrating an exemplary manufacturing method of the template 100 according to the first embodiment.

First, as illustrated in FIG. 7A, the transparent conductive film 30 is formed on the surface S20 of the substrate 20, and the member 40 is formed on the transparent conductive film 30. Thereafter, the member 40 is formed into a stepped pattern, a mask material (first mask material) 60 is formed along the stepped pattern on the member 40, and a mask material (second mask material) 70 is formed on the mask material 60.

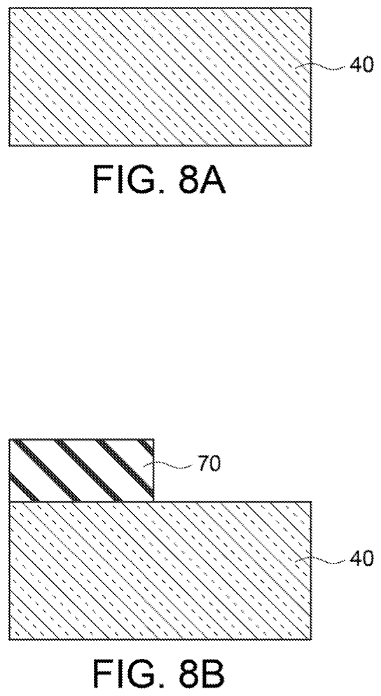

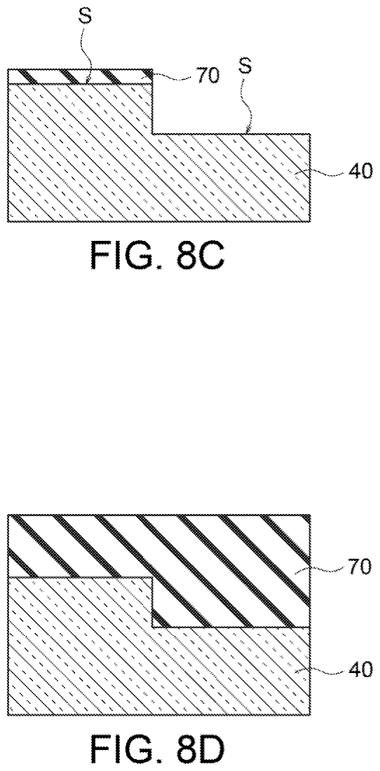

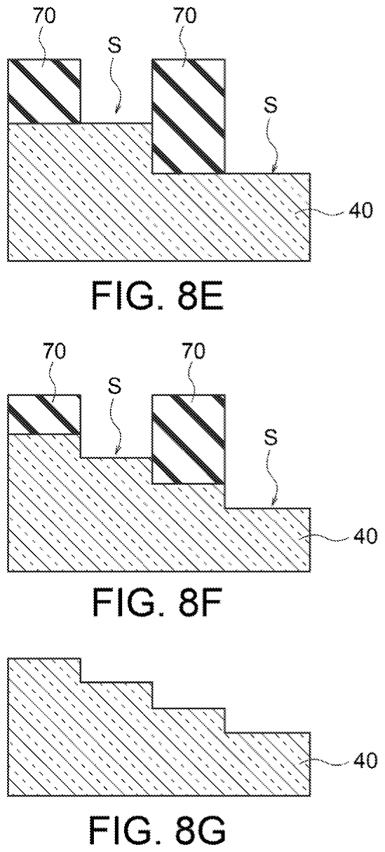

The stepped pattern is a pattern in which the heights of footboard surfaces S sequentially increase or decrease in a certain direction. Specifically, the stepped pattern includes a footboard surface S having a first height and a footboard surface S having a second height different from the first height. The forming method of the stepped pattern will be described later with reference to FIGS. 8A to 8G.

The transparent conductive film 30 and the member 40 are formed by, for example, sputtering.

The mask material 60 is, for example, a chromium (Cr) containing film. The chromium containing film may contain chromium only or may contain carbon (C), oxygen (O), nitrogen (N), or the like as well. The mask material 60 has a film thickness with which the mask material 60 remains even when SiO₂ of the member 40 is processed at maximum. The film thickness of the mask material 60 is set to be, for example, larger than a value obtained by dividing the amount of maximum processing of the member 40 by a selection ratio of the mask material 60 at processing of the member 40. The film thickness of the mask material 60 is, for example, 2 nm approximately to 300 nm approximately. The lower limit of the film thickness of the mask material 60 is determined depending on natural oxidation reaction. The mask material 60 is entirely oxidized when the film thickness of the mask material 60 is smaller than the lower limit. For example, chromium oxide has a plasma resistance lower than that of chromium and thus potentially does not appropriately function as a mask material. The upper limit of the film thickness of the mask material 60 is determined depending on film stress. A defect such as film peeling is potentially likely to occur when the film thickness of the mask material 60 is larger than the upper limit.

The mask material 70 is, for example, a novolak resin resist or a resist containing poly hydroxy styrene (PHS) as a base resin.

FIGS. 8A to 8G are cross sectional views illustrating an exemplary forming method of a stepped pattern according to the first embodiment. In the example illustrated in FIGS. 8A to 8G, a stepped pattern with four steps is formed through two iterations of lithography.

First, as illustrated in FIG. 8A, the member 40 is formed on the transparent conductive film 30 (not illustrated). The top surface of the member 40 has a substantially constant height.

Subsequently, as illustrated in FIG. 8B, the mask material 70 is formed on the member 40. The mask material 70 is, for example, a resist. The mask material 70 has a pattern formed by lithography. Lithography is performed by using, for example, laser drawing and alkaline development. In the example illustrated in FIG. 8B, the mask material 70 is formed on the left half of the top surface of the member 40.

Subsequently, as illustrated in FIG. 8C, the member 40 is processed by using the mask material 70 as a mask. Accordingly, footboard surfaces S as two steps are formed.

Subsequently, as illustrated in FIG. 8D, the mask material 70 is formed on the member 40 again.

Subsequently, as illustrated in FIG. 8E, the mask material 70 is formed into a pattern by lithography. In the example illustrated in FIG. 8E, the mask material 70 is formed on the left half of each footboard surface S.

Subsequently, as illustrated in FIG. 8F, the member 40 is processed by using the mask material 70 as a mask. Accordingly, footboard surfaces S as four steps are formed. In this manner, a stepped pattern with four steps is formed through two iterations of lithography.

Subsequently, as illustrated in FIG. 8G, the mask material 70 is removed.

As illustrated in FIGS. 8A to 8G, etching is performed with different positions and widths of the mask material 70. A stepped pattern with 2ⁿ steps can be formed, where n represents the number of iterations of lithography.

As illustrated in FIG. 7A, a micro trench (groove) T is formed at an end part of a footboard surface S in some cases. In a known model, the micro trench is formed in the process of dry processing as etching is promoted by ions reflected by a sidewall and charge-up of the substrate (member 40).

When the micro trench T exists near a region in which a convex part 41 of the concave-convex pattern is to be formed, anomaly potentially occurs to the height and shape of the convex part 41. For this reason, each convex part 41 is formed at a position separated from the micro trench T.

Subsequently, as illustrated in FIG. 7B, the mask material 70 is formed into pattern elements P1. The formation of the pattern elements P1 from the mask material 70 is performed by using, for example, electron beam (EB) lithography, but not limited thereto and may be performed by using the nanoimprint method.

The width of each pattern element P1 of the mask material 70 corresponds to the width of each convex part 41 and is smaller than the width of each footboard surface S of the stepped pattern. Each pattern element P1 of the mask material 70 is formed in a region separated from the end part of each footboard surface S so that the mask material 70 is separated from the micro trench T. The width of each component is, for example, a width in a direction parallel to the substrate 20.

Subsequently, as illustrated in FIG. 7C, the mask material 60 is processed by using the mask material 70 in the pattern elements P1 as a mask. The processing of the mask material 60 is performed by using, for example, plasma under a condition of chlorine (Cl₂) gas having high selectiveness for quartz (SiO₂) of the member 40.

As the condition of plasma processing of the mask material 60, gas is, for example, mixed gas of chlorine (Cl₂) and oxygen (O₂). The ratio of mixture of chlorine and oxygen is, for example, 5:1. Process pressure is, for example, 0.2 Pa approximately to 40 Pa approximately. Applied power density is, for example, equal to or smaller than 1 W/cm² approximately.

Subsequently, as illustrated in FIG. 7D, the member 40 is processed by using the processed mask material 60 as a mask. The processing of the member 40 is performed by, for example, dry etching. Accordingly, the plurality of convex parts 41 are formed by batch. In the other region than regions in which the convex parts 41 are formed, the member 40 is removed until the transparent conductive film 30 is exposed.

More specifically, the member 40 is processed so that the mask material 60 remains and the transparent conductive film 30 is exposed. Accordingly, the plurality of convex parts 41 having different heights in accordance with the stepped pattern are formed on the top surface (surface S30) of the transparent conductive film 30 corresponding to the surface S100.

As the condition of plasma processing of the member 40, gas is, for example, mixed gas of oxygen (O₂) and gas containing fluorine (F). The gas containing fluorine is, for example, CF₄. The ratio of mixture of CF₄ and O₂ is, for example, 4:1. The process pressure is, for example, 0.2 Pa approximately to 40 Pa approximately. The applied power density is, for example, equal to or smaller than 1 W/cm² approximately.

The transparent conductive film 30 functions as a stopper layer. Thus, processing stops at the transparent conductive film 30. Accordingly, a processing time can be extended (over-etching) to reduce etching residue.

Since the mask material 60 remains, a top part of each convex part 41 is not affected by the process illustrated in FIG. 7D. Thus, the top part of each convex part 41 is substantially rectangular.

Subsequently, as illustrated in FIG. 7E, the mask material 60 is removed. Thereafter, the protective film 50 is formed, and accordingly, the template 100 illustrated in FIG. 6 is completed. The protective film 50 is deposited by, for example, atomic layer deposition.

Subsequently, a manufacturing method of the semiconductor device by using the template 100 will be described below.

First, a resist material is applied or dropped onto a substrate (wafer). The substrate is, for example, a processing target substrate (processing target wafer) including a semiconductor substrate (semiconductor wafer such as a silicon wafer) and a processing target film on the semiconductor substrate. The semiconductor substrate is, for example, the substrate 1 illustrated in FIG. 1, and the processing target film includes, for example, the laminated body 120 illustrated in FIG. 2. In a case in which the semiconductor substrate is processed, the substrate may include no processing target film. The substrate is an exemplary wafer, and the resist material is as an exemplary resin.

Subsequently, a pattern formation surface of the template 100 described above is impressed against the resist material, and then the resist material is cured. Accordingly, the concave-convex pattern of the template 100 is transferred onto the resist material.

Subsequently, the template 100 is released from the resist material. Accordingly, a resist film made of the cured resist material and having a resist pattern is formed on the substrate. This ends processing using the template 100.

As described above, according to the first embodiment, the plurality of convex parts 41 have different heights. The heights of the plurality of convex parts 41 correspond to the heights of footboard surfaces S in the stepped pattern formed on the member 40. The plurality of convex parts 41 are provided as protrusions toward the side opposite the substrate 20 from the top surface of the transparent conductive film 30 corresponding to the surface S100. Accordingly, the transparent conductive film 30 exists around the base of each convex part 41, which can prevent generation of micro trenches T around the convex part 41. Moreover, since the transparent conductive film 30 functions as a stopper layer, the processing time can be extended to reduce etching residue. Accordingly, the pattern of the template 100 can be more appropriately formed. Since the template 100 having a more appropriate pattern is obtained, a semiconductor device having a more appropriate transfer pattern can be manufactured.

The following describes a comparative example in which no stepped pattern is formed and a mask material (resist) having a height in accordance with the heights of the convex parts 41 is formed. In the comparative example, no transparent conductive film 30 is provided.

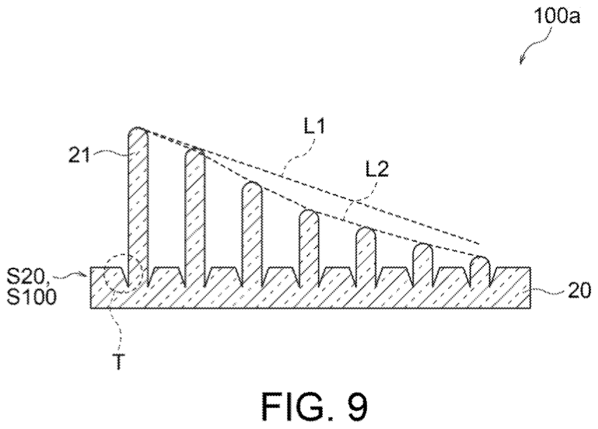

FIG. 9 is a cross sectional view illustrating an exemplary configuration of a template 100a according to the comparative example.

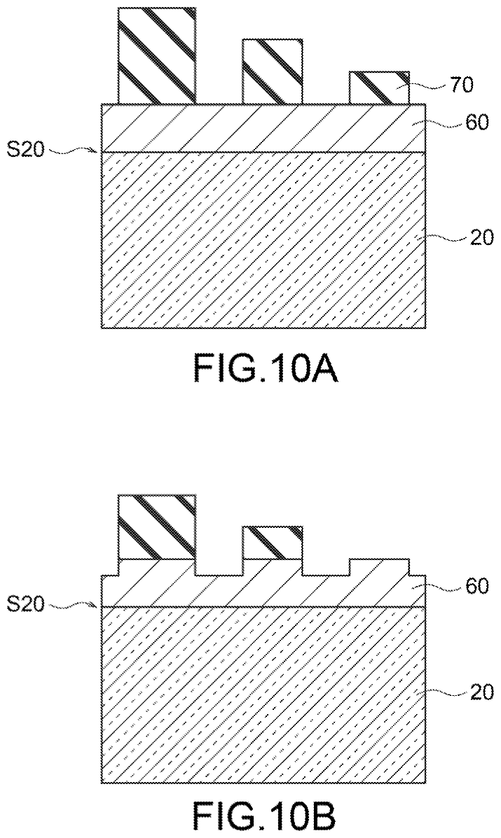

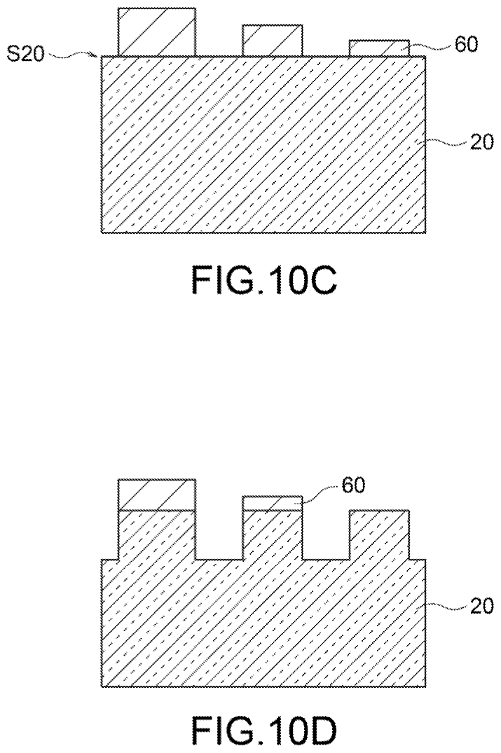

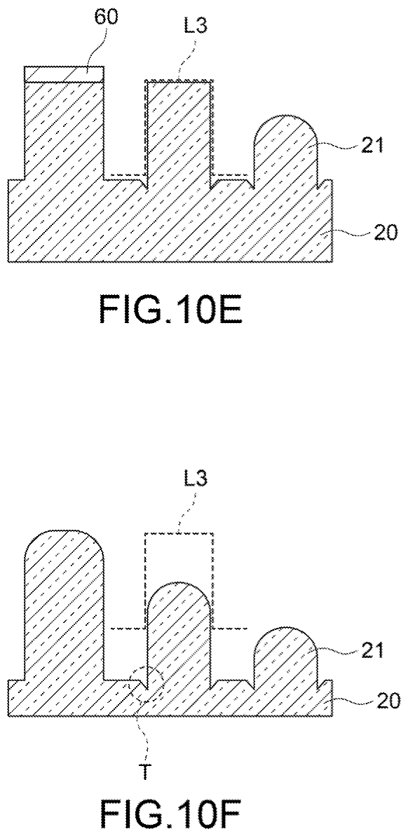

In the example illustrated in FIG. 9, a top part of each convex part 21 of the substrate 20 is rounded. This rounding (shoulder rounding) of the top part of each convex part 21 occurs due to rounding of corners of the convex part 21 as described later with reference to FIGS. 10E and 10F.

A dashed line L1 illustrated in FIG. 9 indicates ideal heights of the convex parts 21. The dashed line L1 indicates that the heights of the convex parts 21 linearly change. A dashed line L2 is a line connecting the top parts of the convex parts 21 illustrated in FIG. 9. The dashed line L2 deviates from the dashed line L1. In other words, the heights of the convex parts 21 have variations.

Furthermore, micro trenches T are formed at the base of each convex part 21.

FIGS. 10A to 10F are cross sectional views illustrating an exemplary manufacturing method of the template 100a according to the comparative example.

First, as illustrated in FIG. 10A, the mask material 60 is formed on the substrate 20, the mask material 70 is formed on the mask material 60, and the mask material 70 is formed into a pattern. The pattern of the mask material 70 is formed to have different heights in accordance with the heights of the convex parts 21. FIG. 10A illustrates an example in which three convex parts 21 are formed.

Subsequently, as illustrated in FIG. 10B, the mask material 60 is processed by using the mask material 70 as a mask.

Subsequently, as illustrated in FIG. 10C, processing of the substrate 20 by using the mask material 60 as a mask is started.

Subsequently, as illustrated in FIG. 10D, the process illustrated in FIG. 10C is continued to process the substrate 20 by using the mask material 60 as a mask. In the example illustrated in FIG. 10D, the mask material 60 corresponding to the right convex part 21 disappears.

Subsequently, as illustrated in FIG. 10E, the process illustrated in FIG. 10D is continued to process the substrate 20 by using the mask material 60 as a mask. The top part of the right convex part 21 is rounded through the processing. The mask material 60 of the center convex part 21 disappears.

Subsequently, as illustrated in FIG. 10F, the process illustrated in FIG. 10E is continued to process the substrate 20 by using the mask material 60 as a mask. Accordingly, the template 100a illustrated in FIG. 9 is completed. In the example illustrated in FIG. 10F, the mask material 60 all disappears and the top parts of the three convex parts 21 are rounded.

In the comparative example, as illustrated in FIGS. 10D to 10F, the mask material 60 disappears halfway through processing, and etching proceeds simultaneously on both of the top and bottom surface of the pattern (both-side etching). The top part of each convex part 21 preferably has a rectangular shape illustrated with a dashed line L3, but the mask material 60 disappears halfway through processing, and thus the top part of the convex part 21 is rounded. This is because etching of the top part of the convex part 21, which is not protected by the mask material 60, proceeds from sides as well. Difference in the proceeding degree of etching in the lateral direction potentially causes variance in the heights of the convex parts 21. Furthermore, micro trenches T are formed in the substrate around each convex part 21. This is because, for example, charge-up occurs due to quartz of the substrate 20 and etching locally proceeds. The rounding of the top part of each convex part 21, the variance in the heights of the convex parts 21, and the micro trenches T at the base of each convex part 21 adversely affect a transferred pattern.

However, in the first embodiment, the mask material 60 remains until processing to form the convex parts 41 is completed, and thus rounding of the top part of each convex part 41 and variance in the heights of the convex parts 41 can be reduced. Moreover, in the first embodiment, each convex part 41 is formed at a position separated from a micro trench T that occurs to the stepped pattern, and thus is not affected by the micro trench T that occurs to the stepped pattern. In addition, the transparent conductive film 30 is provided at bottom parts for forming the convex parts 41, and thus charge-up can be prevented and no micro trenches T are formed around the bases of the convex parts 41. Thus, in the first embodiment, it is possible to reduce influence of rounding of the top part of each convex part 41, variance in the heights of the convex parts 41, and micro trenches T. As a result, the template 100 having a more appropriate pattern can be formed.

### First Modification of First Embodiment

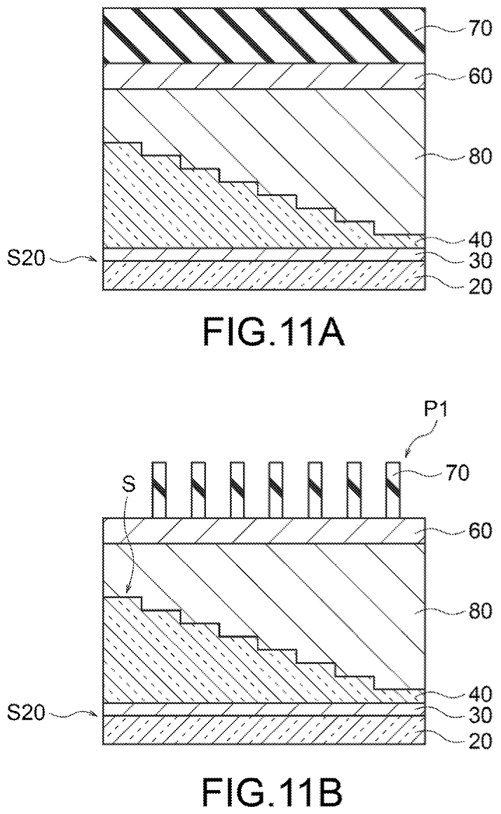

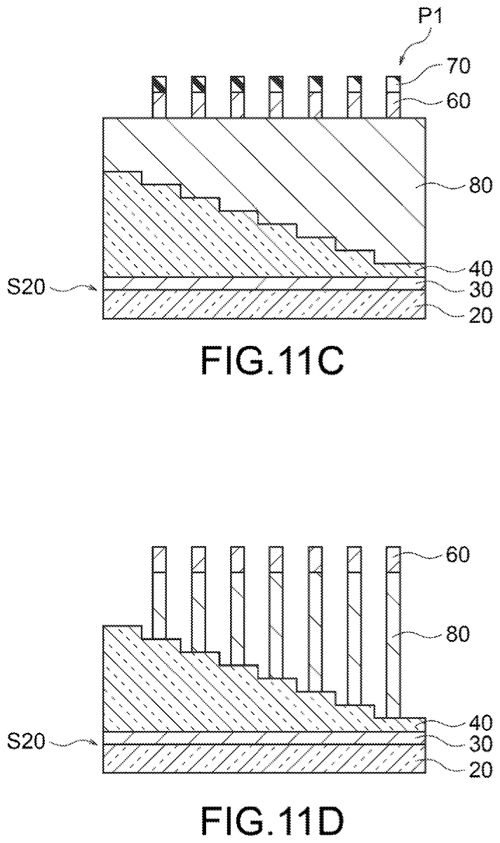

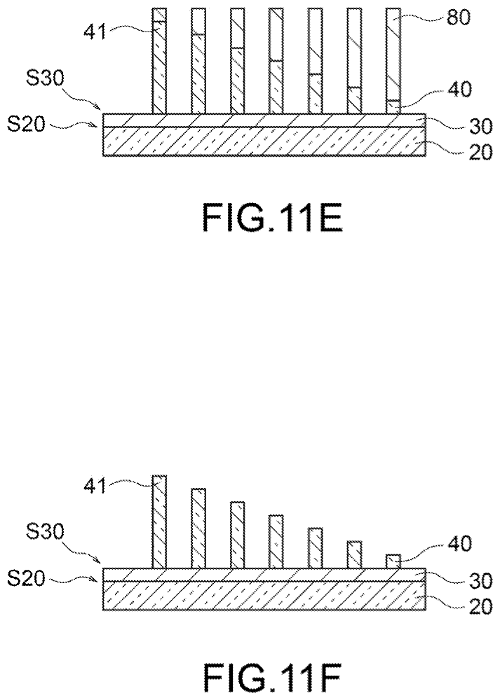

FIGS. 11A to 11F are cross sectional views illustrating an exemplary manufacturing method of the template 100 according to a first modification of the first embodiment. The first modification of the first embodiment is different from the first embodiment in that a material film 80 is formed between the member 40 and the mask material 60.

In the example illustrated in FIG. 11A, similarly to FIG. 7A, after the member 40 is formed into a stepped pattern, the material film 80 is formed on the member 40 and flattened. The flattening of the material film 80 is performed by, for example, chemical mechanical polishing (CMP). Thereafter, the mask material 60 is formed on the material film 80, and the mask material 70 is formed on the mask material 60.

The material film 80 is, for example, a carbon (C) film such as a diamond-like carbon (DLC) film.

Subsequently, as illustrated in FIG. 11B, the mask material 70 is formed into pattern elements P1. The width of each pattern element P1 of the mask material 70 is smaller than the width of each footboard surface S of the stepped pattern.

Subsequently, as illustrated in FIG. 11C, the mask material 60 is processed by using the mask material 70 in the pattern elements P1 as a mask.

Subsequently, as illustrated in FIG. 11D, the material film 80 is processed by using the processed mask material 60 as a mask. The processing of the material film 80 is performed by, for example, ashing with oxygen (O₂) plasma.

As the condition of plasma processing of the material film 80, gas is, for example, oxygen gas but may be nitrogen gas or mixed gas of oxygen and nitrogen. The process pressure is, for example, 0.2 Pa approximately to 40 Pa approximately. The applied power density is, for example, equal to or smaller than 1 W/cm² approximately. The condition of plasma processing of a resist as the mask material 70 may be the same as the condition of plasma processing of the material film 80.

Subsequently, as illustrated in FIG. 11E, the member 40 is processed by using the processed material film 80 as a mask.

More specifically, the member 40 is processed so that the material film 80 remains and the transparent conductive film 30 is exposed. Accordingly, the plurality of convex parts 41 having different heights in accordance with the stepped pattern are formed on the top surface (surface S30) of the transparent conductive film 30 corresponding to the surface S100.

Moreover, since the material film 80 remains as illustrated in FIG. 11E, the top part of each convex part 41 is not affected by dry etching of the member 40. Thus, the top part of each convex part 41 is substantially rectangular.

Subsequently, as illustrated in FIG. 11F, the material film 80 is removed.

Thereafter, the protective film 50 is formed, and accordingly, the template 100 illustrated in FIG. 6 is completed.

In the first modification of the first embodiment, the stepped pattern can be flattened by the material film 80. Accordingly, unlike FIG. 7B in the first embodiment, the pattern elements P1 of the mask material 70 can be formed on a substantially flat surface as illustrated in FIG. 11B. As a result, pattern formation can be more appropriately performed.

As in the first modification of the first embodiment, the material film 80 may be formed between the member 40 and the mask material 60. The template 100 and the semiconductor device according to the first modification of the first embodiment can obtain the same effects as those in the first embodiment.

### Second Modification of First Embodiment

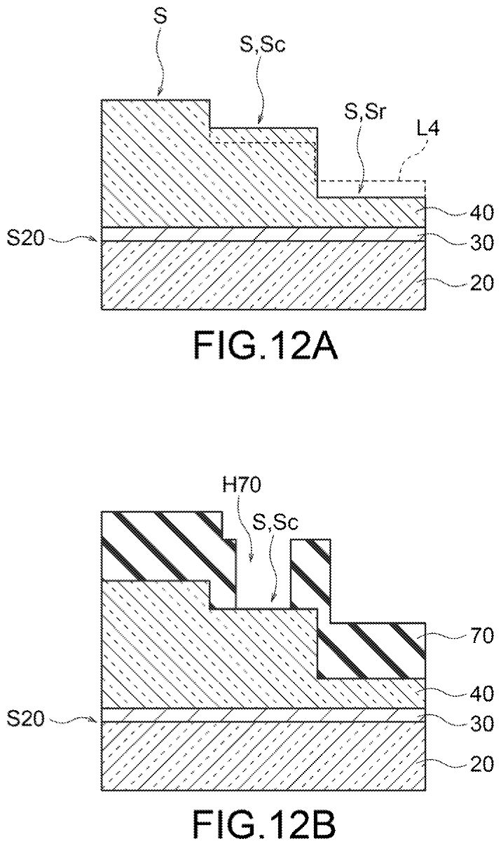

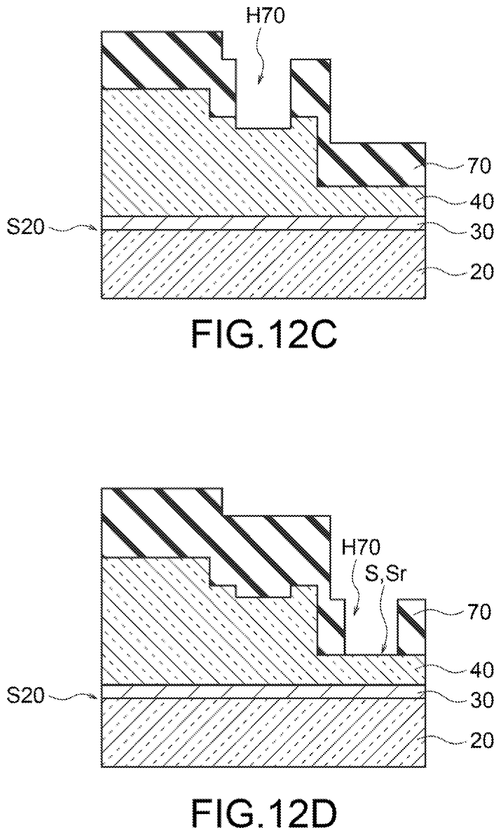

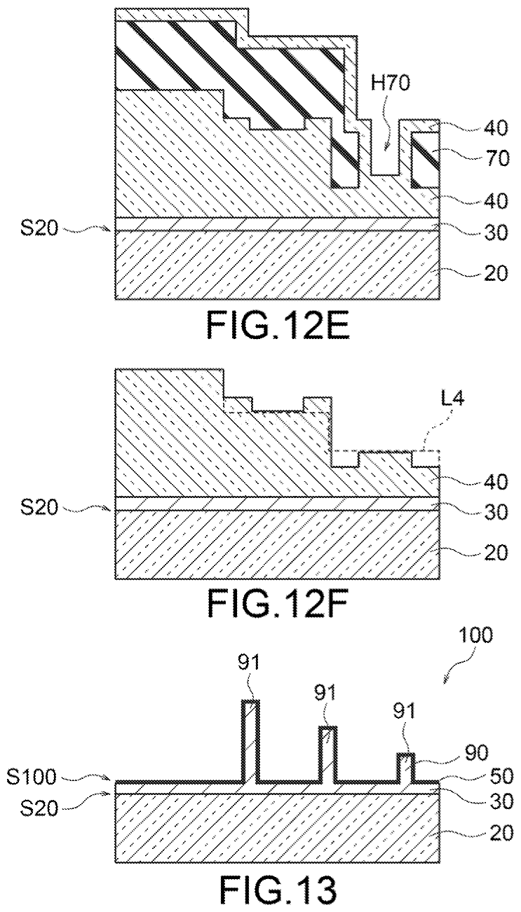

FIGS. 12A to 12F are cross sectional views illustrating an exemplary manufacturing method of the template 100 according to a second modification of the first embodiment. The second modification of the first embodiment is different from the first embodiment in that the heights of footboard surfaces S are corrected after stepped pattern formation.

First, as illustrated in FIG. 12A, the member 40 is formed into a stepped pattern. In the example illustrated in FIG. 12A, the stepped pattern has three footboard surfaces S, and the heights (step differences) of the footboard surfaces S are not equally spaced. A dashed line L4 illustrates an ideal stepped pattern having equally spaced steps. A center footboard surface Sc illustrated in FIG. 12A is higher than the dashed line L4, and a right footboard surface Sr illustrated in FIG. 12A is lower than the dashed line L4. Since the height of each convex part 41 is affected by the height of the corresponding footboard surface S, the height of the convex part 41 can be adjusted by correcting the height of the footboard surface S. As illustrated in FIGS. 7B to 7E, each convex part 41 is formed in a partial region of the corresponding footboard surface S. Thus, the height correction is performed in a region including the region in which the convex part 41 is to be formed. In other words, each footboard surface S includes a region in which the height correction is performed, and the region in which the height correction is performed includes a region in which the corresponding convex part 41 is formed.

Subsequently, the height of each footboard surface S of the stepped pattern is measured. The height measurement of each footboard surface S is performed by using, for example, an atomic force microscope.

Subsequently, in each footboard surface S, the height of the region including at least the region in which the corresponding convex part 41 is to be formed is adjusted based on a result of the height measurement of the footboard surface S. Correction described below is performed based on, for example, the difference between the measured height of the footboard surface S and a height of the footboard surface S, which is set in advance and illustrated with the dashed line L4.

Subsequently, as illustrated in FIG. 12B, the mask material 70 is formed and a hole H70 through which the footboard surface Sc is exposed is formed through the mask material 70. The width of the hole H70 is smaller than the width of the center footboard surface Sc and larger than the width of the region in which the corresponding convex part 41 is to be formed.

Subsequently, as illustrated in FIG. 12C, a partial member of the footboard surface Sc is removed by using the mask material 70 as a mask. Accordingly, the height of the footboard surface Sc is partially decreased. The amount of height adjustment of the footboard surface S is determined depending on the amount of etching the member 40.

Subsequently, as illustrated in FIG. 12D, the mask material 70 is formed again and another hole H70 through which the footboard surface Sr is to be exposed is formed through the mask material 70.

Subsequently, as illustrated in FIG. 12E, a member is formed in the hole H70. The member 40 is deposited by, for example, atomic layer deposition.

Subsequently, as illustrated in FIG. 12F, the mask material 70 is removed. The member formed in the mask material 70 is removed as well. The member 40 formed in the process illustrated in FIG. 12E remains in a region in which the hole H70 is formed (lift-off). Accordingly, the height of the footboard surface Sr can be partially increased. The amount of height adjustment of the footboard surface S is determined depending on the amount of depositing the member 40.

As illustrated in FIG. 12F, the height of a partial region of each footboard surface S can be aligned with the corresponding height of the footboard surface S, which is illustrated with the dashed line L4. The corresponding convex part 41 is formed in the region in which the height is aligned. Accordingly, the height of each convex part 41 can be adjusted by correcting the height of the corresponding footboard surface S after stepped pattern formation. As a result, the pillar pattern of the template 100 has an improved pattern accuracy.

As described above, height measurement is performed for the footboard surfaces S. It is easier to perform height measurement of the footboard surfaces S than height measurement of the convex parts 41.

As in the second modification of the first embodiment, the heights of footboard surfaces S may be corrected after stepped pattern formation. The template 100 and the semiconductor device according to the second modification of the first embodiment can obtain the same effects as those in the first embodiment.

### Third Modification of First Embodiment

FIG. 13 is a cross sectional view illustrating an exemplary configuration of the template 100 according to a third modification of the first embodiment. The third modification of the first embodiment is different from the first embodiment in the composition of convex parts of the template 100.

The template 100 includes a plurality of convex parts 91. The composition of the convex parts 91 is different from the composition of the convex parts 41 in the first embodiment.

The template 100 further includes a transparent conductive member 90.

The transparent conductive member 90 is provided on the transparent conductive film 30. The transparent conductive member 90 includes the plurality of convex parts 91. The composition of the transparent conductive member 90 is different from the composition of the substrate 20. The composition of the convex parts 91 is different from the composition of the convex parts 41 in the first embodiment. The composition of the convex parts 91 is the same as the composition of the transparent conductive film 30. The pillar pattern with the convex parts 91 of the transparent conductive member 90 is sturdier and less likely to break than the pillar pattern with the convex parts 41 of the member 40.

The other configurations of the template 100 and the semiconductor device according to the third modification of the first embodiment are the same as the corresponding configurations of the template 100 and the semiconductor device according to the first embodiment, and thus detailed description thereof is omitted.

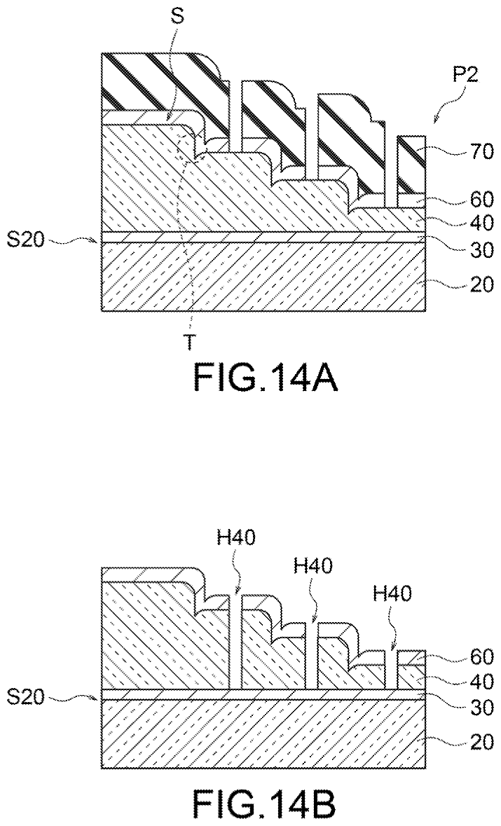

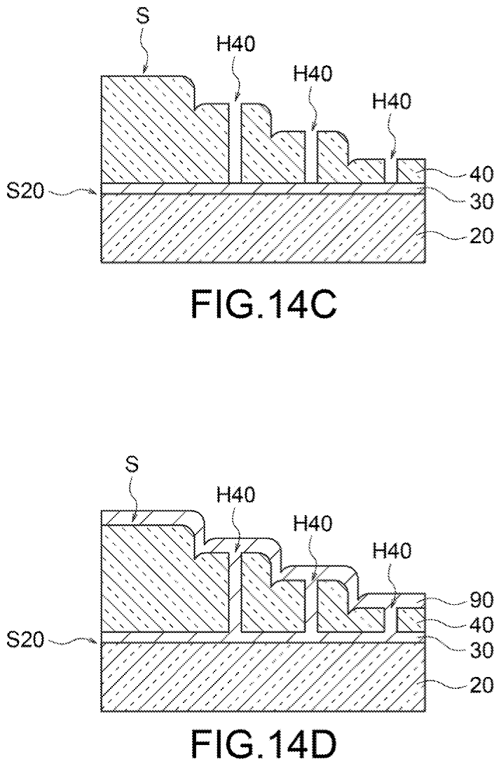

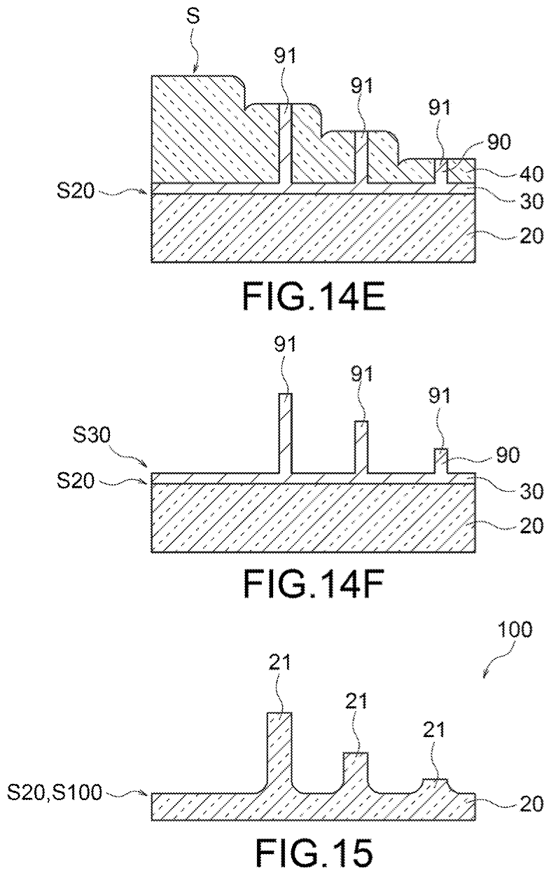

FIGS. 14A to 14F are cross sectional views illustrating an exemplary manufacturing method of the template according to the third modification of the first embodiment.

After the mask material 70 is formed (refer to FIG. 7A), the mask material 70 is formed into pattern elements P2 as illustrated in FIG. 14A and the mask material 60 is processed by using the mask material 70 in the pattern element P2 as a mask.

The width of an opening part of each pattern element P2 of the mask material 70 corresponds to the width of each convex part 91 and is smaller than the width of each footboard surface S of the stepped pattern. The opening part of each pattern element P2 of the mask material 70 is formed in a region separated from an end part of the corresponding footboard surface S so that pattern element P2 is separated from a micro trench T.

Subsequently, as illustrated in FIG. 14B, the member 40 is processed by using the processed mask material 60 as a mask. More specifically, the member 40 is processed so that the transparent conductive film 30 is exposed. Accordingly, holes (first holes) H40 are formed through the member 40. Thereafter, the mask material 70 is removed.

Subsequently, as illustrated in FIG. 14C, the mask material 60 is removed.

Subsequently, as illustrated in FIG. 14D, the transparent conductive member 90 is formed on each footboard surface S and in each hole H40. The transparent conductive member 90 is deposited by, for example, plating and is embedded in each hole H40 and substantially uniformly formed on the stepped pattern (footboard surfaces S). As described above, the composition of the transparent conductive member 90 is the same as the composition of the transparent conductive film 30.

Subsequently, as illustrated in FIG. 14E, the transparent conductive member 90 on the footboard surfaces S is removed until the member 40 is exposed.

The removal of the transparent conductive member 90 is performed by using, for example, iodine (I) gas condition plasma. As the condition of plasma processing of the transparent conductive member 90, gas is, for example, hydrogen iodide (HI) gas.

Subsequently, as illustrated in FIG. 14F, the member 40 is removed. Accordingly, the plurality of convex parts 91 having different heights in accordance with the stepped pattern are formed on the top surface (surface S30) of the transparent conductive film 30 corresponding to the surface S100.

In the process illustrated in FIG. 14E, the transparent conductive member 90 is removed so that a top part of each convex part 91 is exposed on the corresponding footboard surface S as a substantially flat surface, and thus the top part of each convex part 91 illustrated in FIG. 14E is substantially rectangular.

Thereafter, the protective film 50 is formed, and accordingly, the template 100 illustrated in FIG. 13 is completed.

As in the third modification of the first embodiment, the composition of the convex parts of the template 100 may be changed. The template 100 and the semiconductor device according to the third modification of the first embodiment can obtain the same effects as those in the first embodiment.

### Second Embodiment

FIG. 15 is a cross sectional view illustrating an exemplary configuration of the template 100 according to a second embodiment. The second embodiment is different from the first embodiment in that no stepped pattern is formed.

The template 100 according to the second embodiment includes neither the transparent conductive film 30, the member 40, nor the protective film 50.

The substrate 20 includes a plurality of convex parts 21. The plurality of convex parts 21 are provided as protrusions from the surface S20. The plurality of convex parts 21 have different heights.

The other configurations of the template 100 and the semiconductor device according to the second embodiment are the same as the corresponding configurations of the template 100 and the semiconductor device according to the first embodiment, and thus detailed description thereof is omitted.

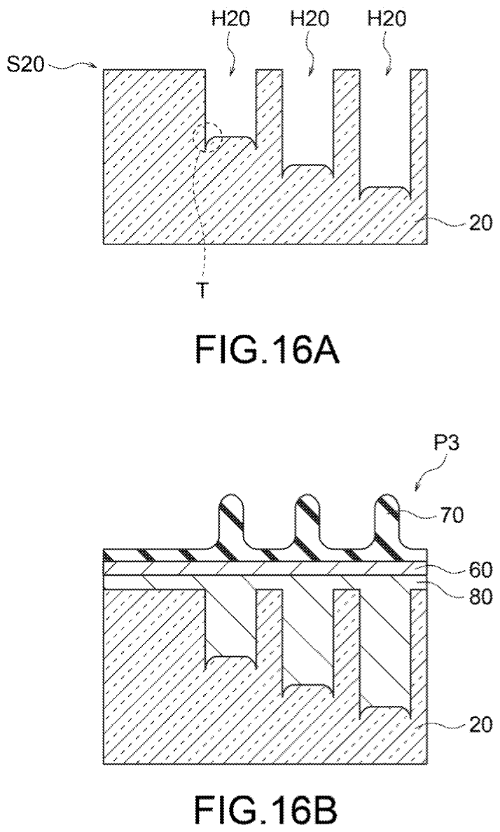

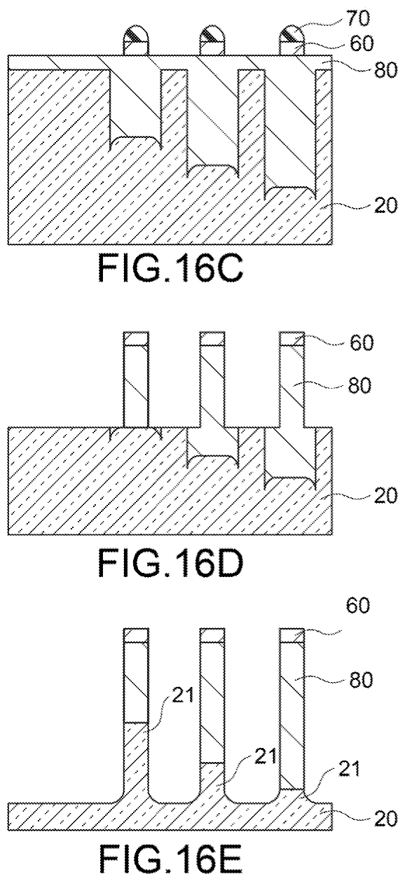

FIGS. 16A to 16E are cross sectional views illustrating an exemplary manufacturing method of the template 100 according to the second embodiment.

First, as illustrated in FIG. 16A, a plurality of holes (second holes) H20 having different depths are formed in the surface S20 of the substrate 20.

Subsequently, as illustrated in FIG. 16B, the material film 80 is formed on the surface S20 and in the plurality of holes H20. Thereafter, the mask material 60 is formed on the material film 80, the mask material 70 is formed on the mask material 60, and the mask material 70 is formed into pattern elements P3.

The width of each pattern element P3 of the mask material 70 corresponds to the width of each convex part 21 and is smaller than the width of each hole H20. Each pattern element P3 of the mask material 70 is formed in a region separated from the end parts of the corresponding hole H20 so that the pattern element P3 is separated from a micro trench T.

The material film 80 is embedded into each hole H20 by, for example, a method of putting the pattern element of the hole H20 into contact with liquid of UV curable resin, filling the hole H20 through capillarity action, and then curing the resin through UV irradiation.

The material film 80 may be flattened after formation of the material film 80. The thickness of the material film 80 beyond necessity leads to a high aspect of a processing mask and potentially adversely affects pattern formation. The height of the processing mask can be adjusted through additional processing of flattening the material film 80.

Subsequently, as illustrated in FIG. 16C, the mask material 60 is processed by using the mask material 70 in the pattern elements P3 as a mask.

Subsequently, as illustrated in FIG. 16D, the substrate 20 and the material film 80 are processed at substantially equal processing speeds by using the processed mask material 60 as a mask. The processing of the substrate 20 and the material film 80 is performed under a condition that, for example, the material film 80 and the substrate 20 can be processed at the selection ratio of about 1:1 in plasma etching using fluorocarbon gas such as CF₄ or CHF₃.

Subsequently, as illustrated in FIG. 16E, the processing illustrated in the process in FIG. 16D is continued to a desired depth. Accordingly, the plurality of convex parts 21 having different heights in accordance with the depths of the plurality of holes H20 are formed on the surface S20 corresponding to the surface S100. The plurality of convex parts 21 are formed by batch.

Thereafter, the mask material 60 is removed, the material film 80 is removed, and accordingly, the template 100 illustrated in FIG. 15 is completed. The removal of the mask material 60 is performed by using, for example, plasma under a condition of chlorine (Cl₂) gas having high selectiveness for quartz of the substrate 20. The removal of the material film 80 is performed by, for example, ashing with oxygen (O₂) plasma.

The material film 80 exists on the sidewall of each convex part 21 (pillar pattern) halfway through processing in the processes illustrated in FIGS. 16D and 16E, and thus it is expected that sidewall sputtering of reflected ions provides a deposition effect. Accordingly, immaterial micro trenches are generated at a bottom part of a pillar pattern obtained as a final shape in some cases when no transparent conductive film 30 is provided, or the base of each convex part 21 has a taper shape as illustrated in FIG. 15 in some cases.

In the second embodiment, no stepped pattern is formed but a pattern of the holes H20 having relatively large widths are formed and a pillar pattern of the convex parts 21 having widths smaller than the widths of the holes H20 is formed. The heights of the convex parts 21 are determined depending on the depths of the holes H20 having relatively large widths.

Unlike the stepped pattern, the pattern of the holes H20 does not need to have a height that sequentially changes. For example, when a hole pattern with which the heights of the convex parts 21 are different at positions is formed, the pattern of the holes H20 is formed in the substrate 20 instead of the stepped pattern.

As in the second embodiment, no stepped pattern may be formed. The template 100 and the semiconductor device according to the second embodiment can obtain the same effects as those in the first embodiment.

### Modification of Second Embodiment

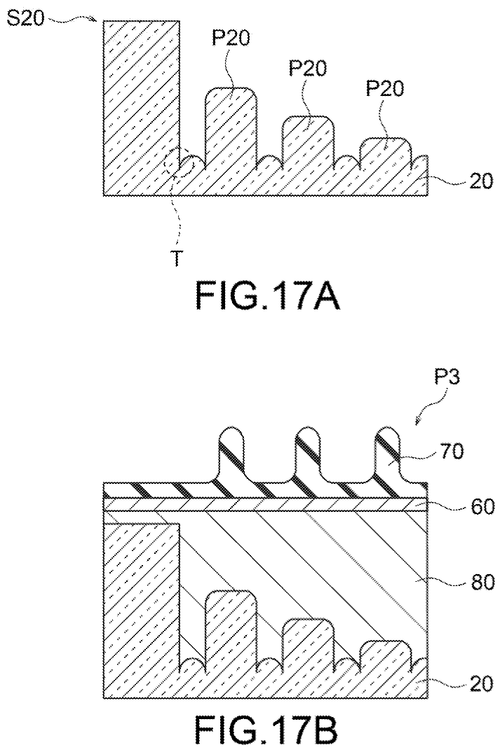

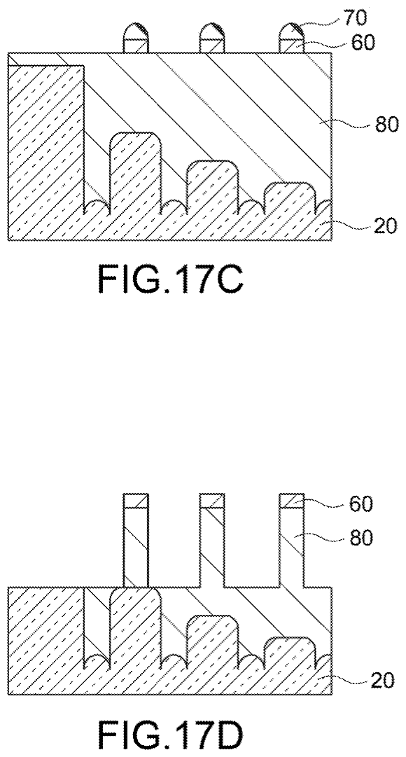

FIGS. 17A to 17D are cross sectional views illustrating an exemplary manufacturing method of the template 100 according to a modification of the second embodiment. The modification of the second embodiment is different from the second embodiment in that pillars P20 are formed on the surface S20 of the substrate 20 in place of the holes H20.

First, as illustrated in FIG. 17A, the surface S20 of the substrate 20 is formed into a plurality of pillars (column-shaped parts) P20 having different heights.

Subsequently, as illustrated in FIG. 17B, the material film 80 is formed on the surface S20 and the plurality of pillars P20. Thereafter, the mask material 60 is formed on the material film 80, the mask material 70 is formed on the mask material 60, and the mask material 70 is formed into pattern elements P3.

The width of each pattern element P3 of the mask material 70 corresponds to the width of each convex part 21 and is smaller than the width of each pillar P20. Each pattern element P3 of the mask material 70 is formed in a region separated from the end parts of the corresponding pillar P20 so that the pattern element P3 is separated from a micro trench T.

The material film 80 may be flattened after formation of the material film 80. The thickness of the material film 80 beyond necessity leads to a high aspect of a processing mask and potentially adversely affects pattern formation. The height of the processing mask can be adjusted through additional processing of flattening the material film 80.

Subsequently, as illustrated in FIG. 17C, the mask material 60 is processed by using the mask material 70 in the pattern elements P3 as a mask. The process in FIG. 17C is substantially the same as the process in FIG. 16C.

Subsequently, as illustrated in FIG. 17D, the substrate 20 and the material film 80 are processed at substantially equal processing speeds by using the processed mask material 60 as a mask. The process in FIG. 17D is substantially the same as the process in FIG. 16D.

Thereafter, similarly to FIG. 16E, the processing illustrated in the process in FIG. 17D is continued to a desired depth. Accordingly, the plurality of convex parts 21 having different heights in accordance with the heights of the plurality of pillars P20 are formed on the surface S20 corresponding to the surface S100. The plurality of convex parts 21 are formed by batch.

Thereafter, the mask material 60 is removed, the material film 80 is removed, and accordingly, the template 100 illustrated in FIG. 15 is completed.

As in the modification of the second embodiment, the pillars P20 may be formed in place of the holes H20. The template 100 and the semiconductor device according to the modification of the second embodiment can obtain the same effects as those in the second embodiment.

In the second embodiment and the modification of the second embodiment, the formation of the mask 60 may be omitted and the mask 70 may be formed directly on the material film 80. In this case, in FIGS. 16D and 17D, the template of the second embodiment is manufactured by processing the substrate 20 and the material film 80 at substantially the same processing speed by using the mask 70 instead of the mask 60. The processing of the substrate 20 and material film 80 using the mask 70 is performed by plasma etching using, for example, a fluorocarbon-based gas such as CF₄ or CHF₃, or a fluorine-based gas such as SF₆ or NF₃.

### Third Embodiment

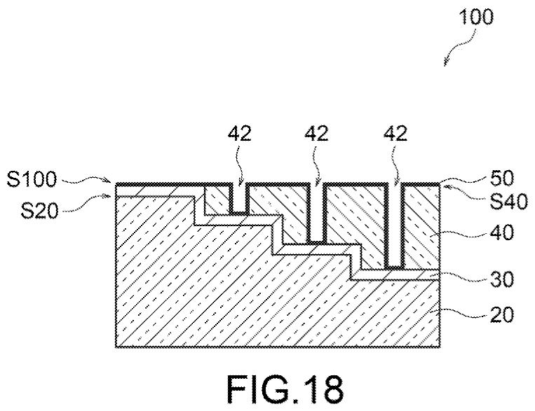

FIG. 18 is a cross sectional view illustrating an exemplary configuration of the template 100 according to a third embodiment. The third embodiment is different from the first embodiment in that the concave-convex pattern of the template 100 is a hole pattern instead of a pillar pattern.

The template 100 includes a plurality of concave parts 42. The plurality of concave parts 42 provided on the surface S100 constitute a hole pattern as the concave-convex pattern.

The hole pattern of the template 100 according to the third embodiment illustrated in FIG. 18 has concave-convex parts inverted with respect to those of the pillar pattern of the template 100 illustrated in FIG. 6 according to the first embodiment. The template 100 illustrated in FIG. 18 is used as a master template to form a replica template. The replica template has concave-convex parts inverted through transfer and thus has a pillar pattern same as that of the template 100 illustrated in FIG. 6. The semiconductor device is formed by using the replica template. In other words, a plurality of concave parts (contact holes H1 to H5) having different depths and used to form the contact plugs 11 can be formed by using the replica template. For example, no transparent conductive film 30 may be provided to the replica template formed from the template 100 illustrated in FIG. 18.

A stepped pattern is provided on the surface S20 of the substrate 20.

The transparent conductive film 30 is provided in a film shape (layer shape) along the stepped pattern on the surface S20.

The member 40 is provided on the transparent conductive film 30. The member 40 has a surface (third surface) S40 on a side opposite the transparent conductive film 30. The surface S40 as the top surface of the member 40 is substantially flat. The member 40 includes the plurality of concave parts 42. The plurality of concave parts 42 are provided from the surface S40 as the top surface of the member 40 corresponding to the surface S100 to the transparent conductive film 30. In other words, the plurality of concave parts 42 are recessed up to the transparent conductive film 30 in the stepped pattern. The plurality of concave parts 42 have different depths in accordance with the stepped pattern. The depths of the concave parts 42 are depths in the direction substantially orthogonal to the surface S100.

The composition of the member 40 is the same as the composition of the substrate 20. The composition of the member 40 is, for example, SiO₂.

The protective film 50 covers the transparent conductive film 30 and the member 40 exposed at the plurality of concave parts 42. The protective film 50 covers the plurality of concave parts 42 and the surface S100. More specifically, the protective film 50 is provided along a bottom surface part and a side surface part of each concave part 42, the transparent conductive film 30, and the top surface of the member 40. The composition of the protective film 50 is the same as the composition of the substrate 20. The composition of the protective film 50 is, for example, SiO₂.

The other configurations of the template 100 and the semiconductor device according to the third embodiment are the same as the corresponding configurations of the template 100 and the semiconductor device according to the first embodiment, and thus detailed description thereof is omitted.

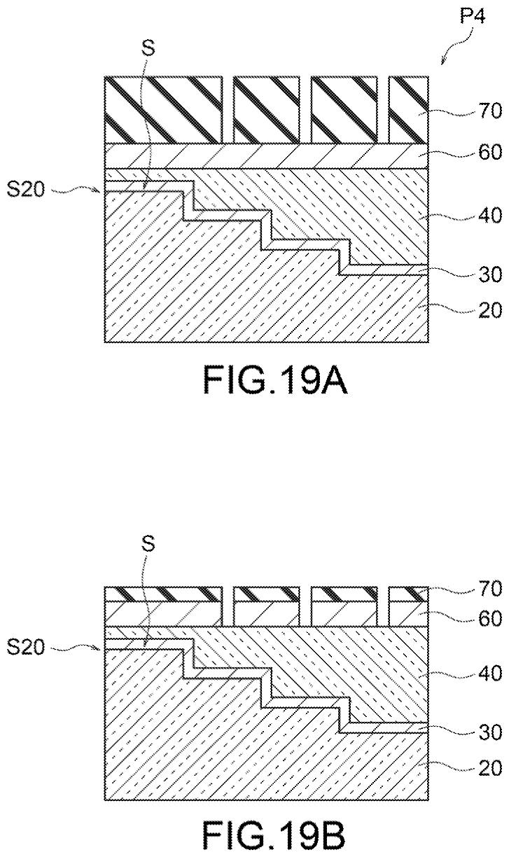

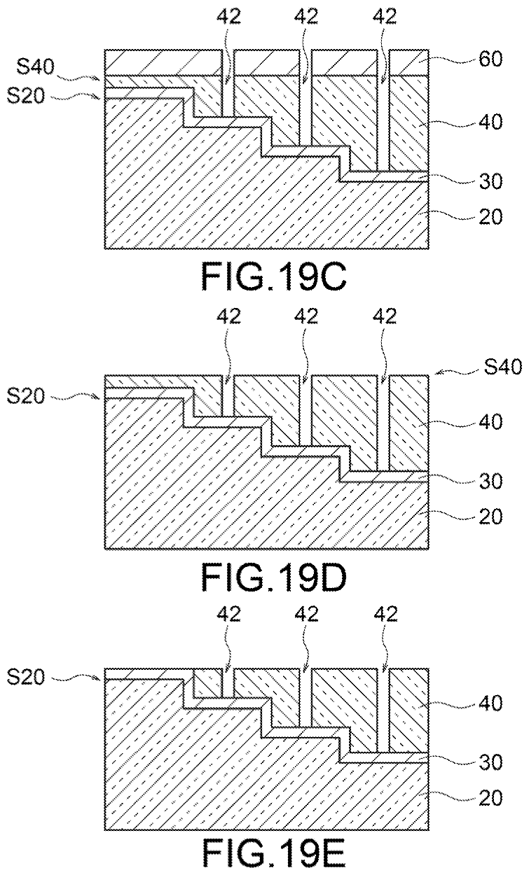

FIGS. 19A to 19E are cross sectional views illustrating an exemplary manufacturing method of the template 100 according to the third embodiment.

First, as illustrated in FIG. 19A, a stepped pattern is formed on the surface S20 of the substrate 20, the transparent conductive film 30 is formed along the stepped pattern on the surface S20 of the substrate 20, the member 40 is formed on the transparent conductive film 30, and the member 40 is flattened. Thereafter, the mask material 60 is formed on the member 40, the mask material 70 is formed on the mask material 60, and the mask material 70 is formed into pattern elements P4. The method of stepped pattern formation on the substrate 20 is the same as the method of stepped pattern formation on the member 40 described with reference to FIGS. 8A to 8G.

The width of an opening part of each pattern element P4 of the mask material 70 corresponds to the width of each concave part 42 and is smaller than the width of each footboard surface S of the stepped pattern. The opening part of each pattern element P4 of the mask material 70 is formed in a region separated from the end parts of the corresponding footboard surface S so that the pattern element P4 is separated from a micro trench T.

Subsequently, as illustrated in FIG. 19B, the mask material 60 is process by using the mask material 70 in the pattern elements P4 as a mask.

Subsequently, as illustrated in FIG. 19C, the member 40 is processed by using the processed mask material 60 as a mask. More specifically, the member 40 is processed so that the transparent conductive film 30 is exposed. Accordingly, the plurality of concave parts 42 having different depths in accordance with the stepped pattern are formed on the top surface of the member 40 (the surface S40) corresponding to the surface S100.

The transparent conductive film 30 functions as a stopper layer. Thus, processing stops at the transparent conductive film 30. Accordingly, the processing time can be extended (over-etching) to reduce etching residue.

Subsequently, as illustrated in FIG. 19D, the mask material 60 is removed.

Subsequently, as illustrated in FIG. 19E, the member 40 is polished until the transparent conductive film 30 is exposed. Thereafter, the protective film 50 is formed, and accordingly, the template 100 illustrated in FIG. 18 is completed.

As in the third embodiment, the concave-convex pattern may be a hole pattern instead of a pillar pattern. The template 100 and the semiconductor device according to the third embodiment can obtain the same effects as those in the first embodiment. The template 100 according to the third embodiment may be combined with the second modification of the first embodiment. In this case, the height of each region including at least a region in which a concave part 42 is formed in the corresponding footboard surface S of the stepped pattern formed on the substrate 20 is adjusted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### (Supplements)

The contents of the above-described embodiments will be supplemented below.

### (Supplement 1)

A manufacturing method of a template, the manufacturing method including:
forming, on a first surface of a substrate, a light transmissive film having a composition different from the composition of the substrate;
forming a first member on the light transmissive film;
forming the first member into a stepped pattern;
forming a first mask material along the stepped pattern on the first member;
forming a second mask material in first pattern elements on the first mask;
processing the first mask material by using the second mask material in the first pattern elements as a mask; and
forming a plurality of convex parts having different heights in accordance with the stepped pattern on a second surface of the light transmissive film on a side opposite the substrate by processing the first member by using the processed first mask material as a mask so that the first mask material remains and the light transmissive film is exposed.

### (Supplement 2)

A manufacturing method of a template, the manufacturing method including:
forming, on a first surface of a substrate, a light transmissive film having a composition different from the composition of the substrate;
forming a first member on the light transmissive film;
forming the first member into a stepped pattern;
forming a material film on the first member;
flattening the material film;
forming a first mask material on the material film;
forming a second mask material in first pattern elements on the first mask;
processing the first mask material by using the second mask material in the first pattern elements as a mask;
processing the material film by using the processed first mask material as a mask; and
forming a plurality of convex parts having different heights in accordance with the stepped pattern on a second surface of the light transmissive film on a side opposite the substrate by processing the first member by using the processed material film as a mask so that the material film remains and the light transmissive film is exposed.

### (Supplement 3)

The manufacturing method of the template according to Supplement 1 or 2, in which the width of each first pattern element of the second mask material corresponds to the width of each convex part and is smaller than the width of each footboard surface of the stepped pattern.

### (Supplement 4)

The manufacturing method of the template according to any one of Supplements 1 to 3, further including, after the formation into the stepped pattern:
measuring the height of each footboard surface of the stepped pattern; and
adjusting, based on a result of the height measurement of the footboard surface, the height of a region including at least a region in which the corresponding convex part is to be formed in the footboard surface.

### (Supplement 5)

A manufacturing method of a template, the manufacturing method including:
forming, on a first surface of a substrate, a light transmissive film having a composition different from the composition of the substrate;
forming a first member on the light transmissive film;
forming the first member into a stepped pattern;
forming a first mask material on the first member;
forming a second mask material in second pattern elements on the first mask material;
processing the first mask material by using the second mask material in the second patterns as a mask;
forming a plurality of first holes through the first member by processing the first member by using the processed first mask material as a mask so that the light transmissive film is exposed;
forming, in the plurality of first holes, a light transmission member having a composition different from the composition of the substrate; and
forming a plurality of convex parts having different heights in accordance with the stepped pattern on a second surface of the light transmissive film on a side opposite the substrate by removing the first member.

### (Supplement 6)

The manufacturing method of the template according to Supplement 5, in which the width of an opening part of each second pattern element of the second mask material corresponds to the width of each convex part and is smaller than the width of each footboard surface of the stepped pattern.

### (Supplement 7)

A manufacturing method of a template, the manufacturing method including:
forming, at a first surface of a substrate, a plurality of second holes having different depths or a plurality of pillars having different heights;
forming a material film on the first surface, and in the plurality of second holes or on the plurality of pillars;
forming a first mask material on the material film;
forming a second mask material in third pattern elements on the first mask material;
processing the first mask material by using the second mask material in the third pattern elements as a mask; and
forming a plurality of convex parts having different heights in accordance with the depths of the plurality of second holes or the heights of the plurality of pillars on the first surface by processing the substrate and the material film at substantially equal processing speeds by using the processed first mask material as a mask.

### (Supplement 8)

The manufacturing method of the template according to Supplement 7, in which the width of each third pattern element of the second mask material corresponds to the width of each convex part and is smaller than the width of each second hole or each pillar.

### (Supplement 9)

A manufacturing method of a template, the manufacturing method including:
forming a stepped pattern at a first surface of a substrate;
forming, along the stepped pattern on the first surface, a light transmissive film having a composition different from the composition of the substrate;
forming a first member on the light transmissive film;
flattening the first member;
forming a first mask material on the first member;
forming a second mask material in fourth pattern elements on the first mask material;
processing the first mask material by using the second mask material in the fourth pattern elements as a mask; and
forming a plurality of concave parts having different depths in accordance with the stepped pattern on a third surface of the first member on a side opposite the light transmissive film by processing the first member by using the processed first mask material as a mask so that the light transmissive film is exposed.

### (Supplement 10)

The manufacturing method of the template according to Supplement 9, in which the width of an opening part of each fourth pattern element of the second mask material corresponds to the width of each concave part and is smaller than the width of each footboard surface of the stepped pattern.

### (Supplement 11)

The manufacturing method of the template according to Supplement 9 or 10, further including, after the formation into the stepped pattern:
measuring the height of each footboard surface of the stepped pattern; and
adjusting, based on a result of the height measurement of the footboard surface, the height of a region including at least a region in which the corresponding concave part is to be formed in the footboard surface.

1. A template comprising:
a substrate having a first surface;
a light transmissive film provided on the first surface, having a second surface on a side opposite to the substrate, and having a composition different from the composition of the substrate; and
a plurality of convex parts provided on the second surface and having different heights.

2. The template according to claim 1, wherein the plurality of convex parts includes a pillar pattern.

3. The template according to claim 1, wherein the light transmissive film has a substantially constant height with respect to the position of the second surface in a direction substantially perpendicular to the second surface.

4. The template according to claim 1, wherein a composition of the convex parts is same as the composition of the substrate or the light transmissive film.

5. The template according to claim 1, wherein the light transmissive film is conductive.

6. The template according to claim 1, further comprising a film having a composition same as the composition of the substrate and covers the plurality of convex parts and the second surface.

7. A template comprising:
a substrate having a first surface provided with a stepped pattern;
a light transmissive film provided along the first surface, having a second surface on a side opposite to the substrate, and having a composition different from the composition of the substrate; and
a first member provided on the second surface and having a third surface on a side opposite to the light transmissive film, wherein
a plurality of concave parts are provided from the third surface of the first member to the light transmissive film, and
the plurality of concave parts have different depths corresponds to the stepped pattern.

8. The template according to claim 7, wherein a composition of the first member is same as the composition of the substrate.

9. The template according to claim 7, further comprising a film having a composition same as the composition of the substrate, and covering both the light transmissive film and the first member that are exposed at the plurality of concave parts.

10. A manufacturing method of a semiconductor device, the manufacturing method comprising:
providing a resin onto a semiconductor substrate;
preparing a template including a substrate, a light transmissive film, and a plurality of convex parts, the substrate having a first surface, the light transmissive film being provided on the first surface, having a second surface on a side opposite to the substrate, and having a composition different from the composition of the substrate, the plurality of convex parts being provided on the second surface and having different heights;
impressing, against the resin, a surface of the template on which the plurality of convex parts are provided;
curing the resin; and
separating the template from the cured resin.

11. The manufacturing method of the semiconductor device according to claim 10, wherein the plurality of convex parts includes a pillar pattern.

12. The manufacturing method of the semiconductor device according to claim 10, wherein the light transmissive film has a substantially constant height with respect to the position of the second surface in a direction substantially perpendicular to the second surface.

13. The manufacturing method of the semiconductor device according to claim 10, wherein a composition of the convex parts is same as the composition of the substrate or the light transmissive film.

14. The manufacturing method of the semiconductor device according to claim 10, wherein the light transmissive film is conductive.

15. The manufacturing method of the semiconductor device according to claim 10, wherein the template further comprises a film having a composition same as the composition of the substrate and covers the plurality of convex parts and the second surface.

16. The manufacturing method of the semiconductor device according to claim 10, wherein the template comprises:
a substrate having a first surface provided with a stepped pattern;
a light transmissive film provided along the first surface, having a second surface on a side opposite to the substrate, and having a composition different from the composition of the substrate; and
a first member provided on the second surface and having a third surface on a side opposite to the light transmissive film, wherein
a plurality of concave parts are provided from the third surface of the first member to the light transmissive film, and
the plurality of concave parts have different depths corresponds to the stepped pattern.

17. The manufacturing method of the semiconductor device according to claim 16, wherein a composition of the first member is same as the composition of the substrate.

18. The manufacturing method of the semiconductor device according to claim 16, wherein the template further comprises a film having a composition same as the composition of the substrate, and covering both the light transmissive film and the first member that are exposed at the plurality of concave parts.
